(19) United States
(12) Patent Application Publication
(10) Pub. No.: US 2013/0214282 A1
(43) Pub. Date: Aug. 22, 2013

(54) III-N ON SILICON USING NANO STRUCTURED INTERFACE LAYER

(71) Applicants: Erdem Arkun, San Carlos, CA (US); Radek Roucka, Mountain View, CA (US); Andrew Clark, Los Altos, CA (US); Robin Smith, Palo Alto, CA (US); Michael Lebby, Apache Junction, AZ (US)

(72) Inventors: Erdem Arkun, San Carlos, CA (US); Radek Roucka, Mountain View, CA (US); Andrew Clark, Los Altos, CA (US); Robin Smith, Palo Alto, CA (US); Michael Lebby, Apache Junction, AZ (US)

(21) Appl. No.: 13/399,334

(22) Filed: Feb. 17, 2012

(51) Int. Cl. H01L 29/20; H01L 21/20

(52) U.S. Cl. 257/76; 438/478; 257/E21.09; 257/E29.089

(57) ABSTRACT

A method of fabricating a layer of single crystal semiconductor material on a silicon substrate including providing a crystalline silicon substrate and epitaxially depositing a nano structured interface layer on the substrate. The nano structured interface layer has a thickness up to a critical thickness. The method further includes epitaxially depositing a layer of single crystal semiconductor material in overlying relationship to the nano structured interface layer. Preferably, the method includes the nano structured interface layer being a layer of coherently strained nano dots of selected material. The critical thickness of the nano dots includes a thickness up to a thickness at which the nano dots become incoherent.

### FIELD OF THE INVENTION

This invention relates in general to the deposition of III-N on silicon wafers and more specifically to the use of nano structured interface layers to compensate strain.

### BACKGROUND OF THE INVENTION

It has been found that III-N materials are a desirable semiconductor material in many electronic and photonic applications. As understood in the art, the III-N semiconductor material must be provided as a crystalline or single crystal formation for the most efficient and useful basis for the fabrication of various electronic and photonic devices therein. Further, the single crystal III-N semiconductor material is most conveniently formed on single crystal silicon wafers because of the extensive background and technology developed in the silicon semiconductor industry. However, efforts to grow III-N on silicon wafers have resulted in substantially bowed wafers due to difference in the thermal expansion coefficient of III-N material and that of silicon. Further, the deposition of the III-N material requires relatively high temperatures and cracking of the III-N material layer during cool down to room temperature is prevalent.

It would be highly advantageous, therefore, to remedy the foregoing and other deficiencies inherent in the prior art.

Accordingly, it is an object of the present invention to provide new and improved methods of growing III-N on silicon substrates using a nano structured interface layer for strain compensation.

It is another object of the present invention to provide a new and improved nano structured interface layer including coherent nano dots.

It is another object of the present invention to provide new and improved methods of providing strain compensation during the epitaxial growth of III-N on silicon.

It is another object of the present invention to provide new and improved strain compensated III-N on silicon wafers.

### SUMMARY OF THE INVENTION

Briefly, the desired objects and aspects of the instant invention are achieved in accordance with a preferred method of fabricating a layer of single crystal semiconductor material on a silicon substrate including providing a crystalline silicon substrate and epitaxially depositing a nano structured interface layer on the substrate. The nano structured interface layer has a thickness up to a critical thickness. The method further includes epitaxially depositing a layer of single crystal semiconductor material in overlying relationship to the nano structured interface layer. Preferably, the method includes the nano structured interface layer being a layer of coherently strained nano dots of selected material. The critical thickness of the nano dots includes a thickness up to a thickness at which the nano dots become incoherent.

The desired objects and aspects of the instant invention are further realized in accordance with a preferred embodiment of a III-N on silicon wafer including a crystalline silicon substrate with a nano structured interface layer epitaxially deposited thereon. Preferably, the nano structured interface layer includes a layer of coherently strained nano dots of selected material. The nano structured interface layer has a thickness up to a critical thickness, which in the case of the nano dots includes a thickness up to that at which the nano dots become incoherent. A layer of single crystal semiconductor material is epitaxially deposited in overlying relationship to the nano structured interface layer.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram illustrating the growth of coherent nano dots on the surface of a silicon wafer;

FIG. 2 (FIGS. 2(a)-2(f)) illustrates some examples of different embodiments of nano structured interface layers; and

FIG. 3 is a simplified layer diagram of a III-N on silicon wafer that is strain compensated with a nano structured interface layer, in accordance with the present invention.

### DETAILED DESCRIPTION OF THE DRAWINGS

It has been found that any attempted growth of a III-N layer directly on silicon, or even in some cases on a rare earth oxide intermediate layer, results in substantial tensile stress in the III-N layer which results in excessive bowing of the wafer. This bowing of the wafer can make the wafer impractical for further processing, resulting in substantial amounts of wasted material and effort. Further, the deposition of the III-N material on silicon wafers requires relatively high temperatures and cracking of the III-N material layer during cool down to room temperature is prevalent due to the tensile stress between materials.

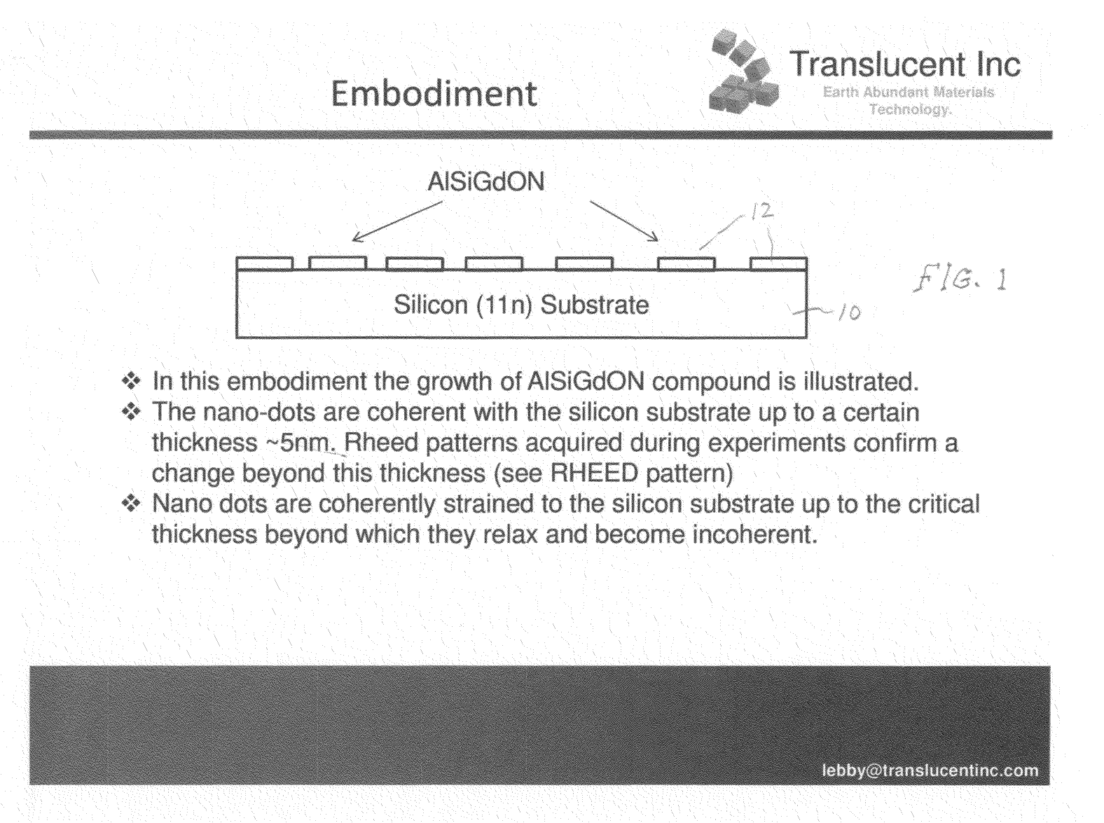

Referring to FIG. 1, a simplified layer diagram is illustrated showing the growth of strained coherent nano dots 12 on the surface of a silicon substrate 10 in accordance with the present invention. Substrate 10 is single crystal silicon which, it will be understood, is or may be a standard well know single crystal silicon wafer or portion thereof generally known and used in the semiconductor industry. Single crystal silicon substrate 10, it will be understood, is not limited to any specific crystal orientation but could include <111> silicon, <110> silicon, <100> silicon or any other silicon crystal orientation or variation known and used in the art.

Nano dots 12 are formed when a selected compound, including any combination of the AlSiGdON family, is deposited on the surface of substrate 10. A typical selected compound is for example (AlₓSi₁₋ₓ)₂O₃ with the X being selected to provide a desired amount of tensile stress at the interface with substrate 10. Generally, any combination of the aluminum, silicon, gadolinium, oxide, nitride, or oxynitride that provides the desired tensile strain can be used. As will be explained in more detail presently, the desired tensile strain should be sufficient to mitigate stresses formed during subsequent growth of III-N material to prevent subsequent III-N layers from cracking during deposition and/or cooling. Whenever III-N materials are mentioned it will be understood that “III-N” materials are generally defined as nitrides of any of the III materials from the periodic table of elements.

In the formation of nano dots 12, the selected material is epitaxially deposited using any of the well known growth methods, such as MBE, MOCVD, PLD (pulsed laser deposition), sputtering, ALD (atomic layer deposition), or any other known growth method for thin films. Each nano dot is coherent with the silicon substrate so that crystal nodes of the selected compound at the interface surface of each nano dot are substantially matched with crystal nodes at the interface surface in the silicon substrate except for the difference in node spacing between the selected compound and the silicon substrate (i.e. the tensile strain). For example, a first node of the nano dot will be exactly matched with a node of the silicon substrate. Adjacent nodes in the nano dot in all directions of the interface surface will be spaced slightly away from the next nodes (or multiples thereof) of the silicon substrate, hence the tensile stress. The next nodes will be spaced even farther from the matching nodes and eventually the tensile stress will be so great that islands or nano dots will form. Because of the formation of the nano dots, the average tensile stress across the entire area of the silicon substrate will be substantially constant.

It has also been found that nano dots 12 are coherent with silicon substrate 10 up to a certain critical thickness, which in the preferred embodiment is approximately 5 nm. Beyond the critical thickness the nano dots relax and become incoherent, that is the crystal nodes of the selected compound no longer match nodes in the silicon substrate. Nano dots formed with the critical thickness (i.e. coherent nano dots) have a smooth morphology (terraces) conducive to epitaxy of III-N compounds thereon. Incoherent (relaxed) nano dots become rough and do not provide the same benefits as the coherently strained quantum dots.

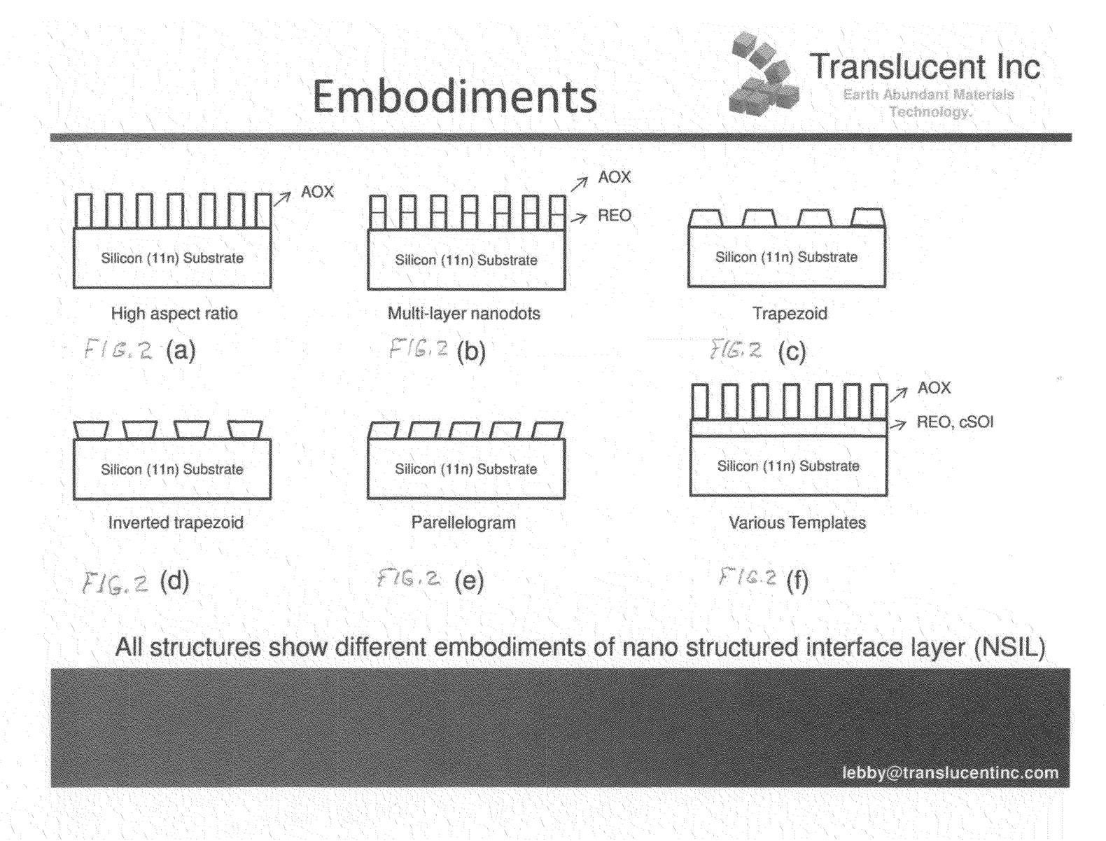

Referring additionally to FIG. 2, several examples or different embodiments of nano structured interface layers (nano dots 12) are illustrated. In FIG. 2(a) the nano structured interface layer includes high aspect ratio nano dots or islands formed only using a selected compound of the AlSiGdON family. In FIG. 2(b) the nano structured interface layer includes nano dots initially formed using a rare earth oxide and then completing the nano dots with a selected compound of the AlSiGdON family. In FIG. 2(c) the nano structured interface layer includes nano dots formed with a trapezoidal shape, in FIG. 2(d) the nano structured interface layer includes nano dots formed with an inverted trapezoidal shape, and in FIG. 2(e) the nano structured interface layer includes nano dots formed with the shape of a parallelogram each produced by changing the selected compound and or the rate or angle of deposition. In FIG. 2(f) the nano structured interface layer includes a first complete layer of a rare earth oxide or a crystalline silicon for a buffer layer with nano dots formed with a selected compound of the AlSiGdON family. It will be understood that other varieties and/or shapes of nano structured interface layers can be devised and all such variations are intended to be included herein.

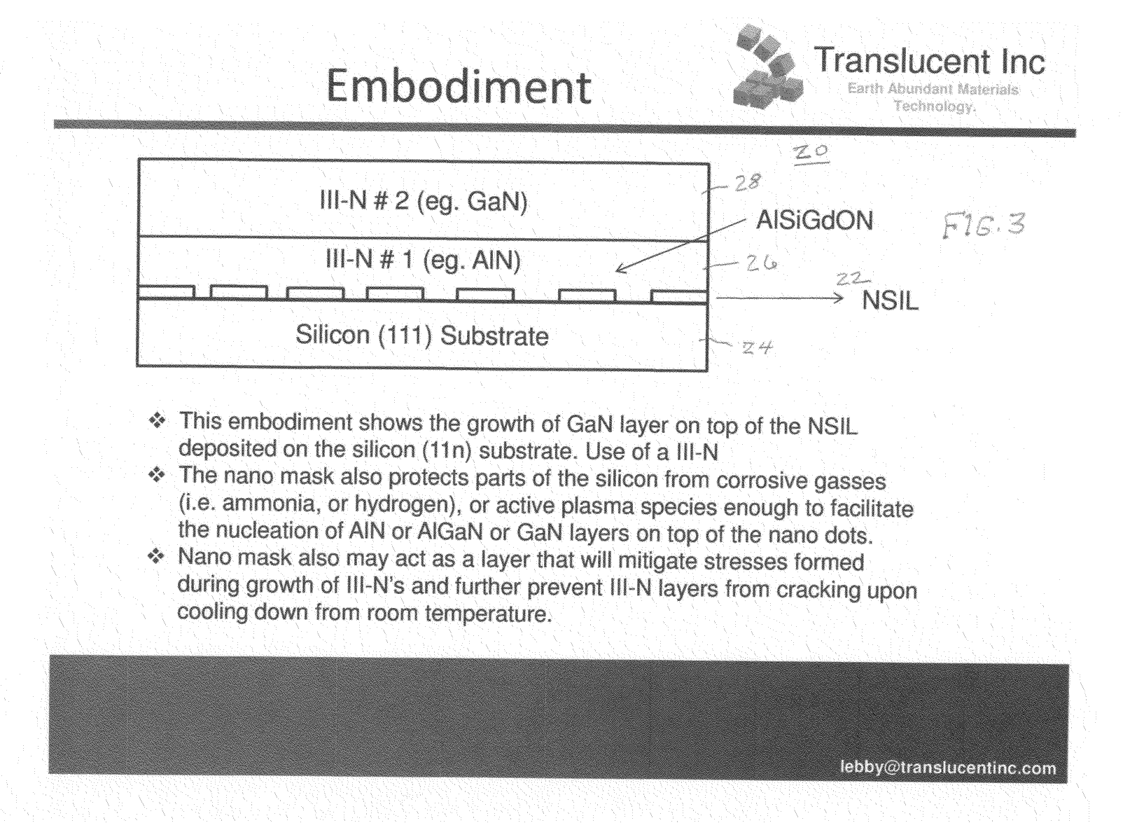

Turning now to FIG. 3, a simplified layer diagram of a III-N on silicon wafer 20 that is strain compensated with a nano structured interface layer 22, in accordance with the present invention, is illustrated. Wafer 20 includes a single crystal silicon substrate 24. While substrate 24 is illustrated as having a <111> crystal orientation it will be understood that it is only for purposes of explanation and can be any crystal orientation as described above. Nano structured interface layer 22 includes any of the various embodiments described above but in this embodiment simple tensile strained coherent nano dots of a selected compound of the AlSiGdON family are illustrated. Nano structured interface layer 22 protects parts of silicon substrate 24 from corrosive gasses (e.g. ammonia or hydrogen) or active plasma species enough to facilitate the nucleation of one or more III-N layers, such as AlN, AlGaN, or GaN, on top of the nano dots.

In silicon wafer 20 a first intermediate layer 26 of lightly strained single crystal material, such as single crystal III-N material (e.g. AlN), is epitaxially deposited directly on nano structured interface layer 22. A layer 28 of III-N semiconductor material is then epitaxially deposited on first intermediate layer 26. Generally, first intermediate layer 26 will be slightly strained relative to nano structured interface layer 22 and substantially crystal lattice matched to layer 28. Typically, nano structured interface layer 22 and first intermediate layer 26 are selected so that little or no strain is present in the final layer, in this example layer 28. That is the final layer is strain compensated with nano structured interface layer 22 and any additional intermediary strain compensating layers. Because a substantial portion of the tensile strain is removed or compensated for in nano structured interface layer 22 through the formation of nano dots any remaining strain can be removed through one or more intermediary layers, such as layer 26, so that any strain that would be present between the final layer (in this example layer 28) and silicon substrate 24 is substantially mitigated. Stated another way, any strain that would be present between the final layer (in this example layer 28) and silicon substrate 24 is reduced in one or more steps by nano structured interface layer 22 and, optionally, one or more intermediary layers 26.

Thus, the nano structured interface layer protects parts of the substrate surface during further growth operations and substantially mitigates stresses formed during growth of the final III-N layer, thus preventing cracking upon cooling after the growth operation. Also, the nano structured interface layer and any intermediary layers included can be formed of relatively simple and inexpensive materials. Further, the entire wafer 20 can be formed in situ or in one continuous operation so that time and labor are substantially reduced, thereby substantially reducing the cost of manufacturing.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of fabricating a layer of single crystal semiconductor material on a silicon substrate comprising the steps of:
providing a crystalline silicon substrate;
epitaxially depositing a nano structured interface layer on the substrate, the nano structured interface layer having a thickness up to a critical thickness; and
epitaxially depositing a layer of single crystal semiconductor material in overlying relationship to the nano structured interface layer.

2. A method as claimed in claim 1 wherein the nano structured interface layer includes a layer of coherently strained nano dots of selected material.

3. A method as claimed in claim 2 wherein the critical thickness includes a thickness up to a thickness at which the nano dots become incoherent.

4. A method as claimed in claim 3 wherein the critical thickness includes a thickness up to a thickness of approximately 5 nm.

5. A method as claimed in claim 2 wherein the layer of selected material includes material with a tensile strain sufficient to mitigate stresses formed during epitaxial deposition of the layer of single crystal semiconductor material so as to prevent the layer of single crystal semiconductor material from cracking during deposition and/or cooling.

6. A method as claimed in claim 5 wherein the layer of selected material includes any combination of aluminum, silicon, gadolinium, oxide, nitride, or oxynitride.

7. A method as claimed in claim 1 including in addition, subsequent to the step of epitaxially depositing the nano structured interface layer and prior to the step of epitaxially depositing a layer of single crystal semiconductor material, epitaxially depositing a layer of intermediate strain compensating material in overlying relationship to the nano structured interface layer.

8. A method as claimed in claim 7 wherein the intermediate strain compensating material includes a III-N material.

9. A method as claimed in claim 1 wherein the layer of single crystal semiconductor material includes a III-N material.

10. A method as claimed in claim 9 wherein the III-N material includes GaN.

11. A method of fabricating a layer of III-N semiconductor material on a silicon substrate comprising the steps of:
providing a crystalline silicon substrate;
epitaxially depositing a layer of coherently strained nano dots of selected material on the substrate, the nano dots having a thickness up to a critical thickness of approximately 5 nm, and the layer of selected material including any combination of aluminum, silicon, gadolinium, oxide, nitride, or oxynitride; and
epitaxially depositing a layer of single crystal III-N semiconductor material in overlying relationship to the layer of coherently strained nano dots.

12. A method as claimed in claim 11 wherein the selected material of the nano dots includes material with a tensile strain sufficient to mitigate stresses formed during epitaxial deposition of the layer of single crystal semiconductor material so as to prevent the layer of single crystal semiconductor material from cracking during deposition and/or cooling.

13. A method as claimed in claim 11 including in addition, subsequent to the step of epitaxially depositing the nano structured interface layer and prior to the step of epitaxially depositing the layer of single crystal semiconductor material, epitaxially depositing a layer of intermediate strain compensating material in overlying relationship to the nano structured interface layer.

14. A method as claimed in claim 13 wherein the intermediate strain compensating material includes a III-N material.

15. A method as claimed in claim 11 wherein the III-N semiconductor material includes GaN.

16. A III-N on silicon wafer comprising:
a crystalline silicon substrate;
a nano structured interface layer epitaxially deposited on the substrate, the nano structured interface layer having a thickness up to a critical thickness; and
a layer of single crystal semiconductor material epitaxially deposited in overlying relationship to the nano structured interface layer.

17. A III-N on silicon wafer as claimed in claim 16 wherein the nano structured interface layer includes a layer of coherently strained nano dots of selected material.

18. A III-N on silicon wafer as claimed in claim 17 wherein the critical thickness includes a thickness up to a thickness at which the nano dots become incoherent.

19. A III-N on silicon wafer as claimed in claim 18 wherein the critical thickness includes a thickness up to a thickness of approximately 5 nm.

20. A III-N on silicon wafer as claimed in claim 17 wherein the layer of selected material includes material with a tensile strain sufficient to mitigate stresses formed during epitaxial deposition of the layer of single crystal semiconductor material so as to prevent the layer of single crystal semiconductor material from cracking during deposition and/or cooling.

21. A III-N on silicon wafer as claimed in claim 20 wherein the layer of selected material includes any combination of aluminum, silicon, gadolinium, oxide, nitride, or oxynitride.

22. A III-N on silicon wafer as claimed in claim 16 including in addition, subsequent to the epitaxially deposited nano structured interface layer and prior to the epitaxially deposited layer of single crystal semiconductor material, a layer of epitaxially deposited intermediate strain compensating material positioned in overlying relationship to the nano structured interface layer.

23. A III-N on silicon wafer as claimed in claim 22 wherein the intermediate strain compensating material includes a III-N material.

24. A III-N on silicon wafer as claimed in claim 16 wherein the layer of single crystal semiconductor material includes a III-N material.

25. A III-N on silicon wafer as claimed in claim 24 wherein the III-N material includes GaN.
